(19) United States
(12) Patent Application Publication
(10) Pub. No.: US 2026/0052980 A1
(43) Pub. Date: Feb. 19, 2026

(54) CAPACITOR STRUCTURE, ELECTRONIC DEVICE AND METHOD OF MANUFACTURING AN ELECTRONIC DEVICE

(71) Applicant: Taiwan Semiconductor Manufacturing Company, Ltd., Hsinchu (TW)

(72) Inventor: Pei-Tien Tsai, Hsinchu City (TW)

(73) Assignee: Taiwan Semiconductor Manufacturing Company, Ltd., Hsinchu (TW)

(21) Appl. No.: 18/803,354

(22) Filed: Aug. 13, 2024

(51) Int. Cl. H01L 23/522; H01L 23/528

(52) U.S. Cl. CPC H01L 23/5223; H01L 23/5226; H01L 23/5283; H10D 1/042; H10D 1/696; H10D 1/716

(57) ABSTRACT

A capacitor structure provided herein includes electrode metal layers sequentially disposed over a substrate. Each electrode metal layer includes bus lines, opposite bus lines and finger electrodes arranged in parallel between the bus lines and the opposite bus lines. Odd finger electrodes in the each electrode metal layer are connected to the bus lines in an adjacent electrode metal layer, and even finger electrodes in the each electrode metal layer are connected to the opposite bus lines in the adjacent electrode metal layers. An underlying metal layer is disposed under a bottom most electrode metal layer and includes an underlying bus line. Underlying conductive vias connect the odd finger electrodes in the bottom most electrode metal layers to the underlying bus line. Two adjacent odd finger electrodes in the bottom most electrode metal layers are connected to different bus lines in the adjacent electrode metal layer through interlayer conductive vias.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. To continue decreasing the size of features in integrated circuits, various thin-film deposition techniques, etching techniques, and other processing techniques are implemented. These techniques can form very small features. However, there are many difficulties involved in ensuring high performance of the devices and features.

### BRIEF DESCRIPTION OF THE DRAWINGS

FIG. 1 schematically illustrates an electronic device in accordance with some embodiments of the disclosure.

FIG. 2 schematically illustrates an i^{th} layer of the metal layers forming the capacitor structure in accordance with some embodiments of the disclosure.

FIG. 3 schematically illustrates the (i+1)^{th} layer of the metal layers forming the capacitor structure in accordance with some embodiments of the disclosure.

FIG. 4 schematically illustrates the j^{th} layer of the metal layers forming the capacitor structure in accordance with some embodiments of the disclosure.

FIG. 5 schematically illustrates the underlying metal layer of the capacitor structure in accordance with some embodiments of the disclosure.

FIGS. 6-8 schematically illustrate respective cross sections of the capacitor structure taken along lines A-A, B-B and C-C in FIG. 1, respectively.

FIGS. 9-14 schematically illustrate the connection between the finger electrodes in the bottom most layer of the electrode metal layers and the underlying metal layer in accordance with some embodiments of the disclosure.

FIGS. 15-17 schematically illustrate further metal layers in the electronic device in accordance with some embodiments of the disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

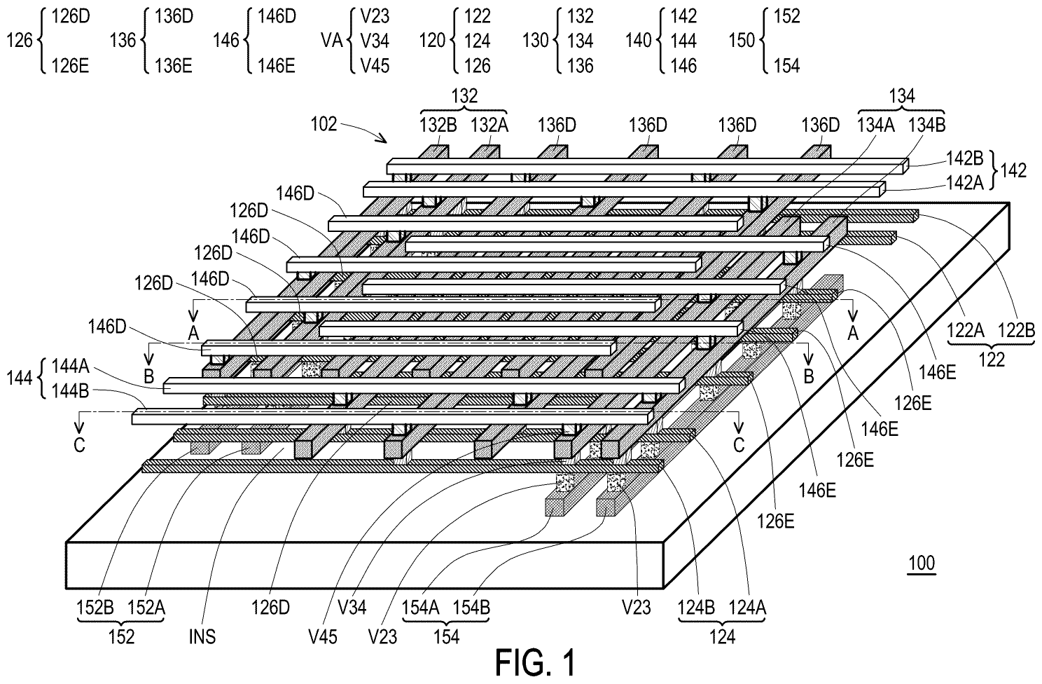

FIG. 1 schematically illustrates an electronic device in accordance with some embodiments of the disclosure. An electronic device 100 in FIG. 1 includes a substrate 110 and metal layers ML sequentially disposed over the substrate 110. In some embodiments, the electronic device 100 further includes an insulation structure INS over the substrate 110 and disposed between the metal features of the metal layers ML. In some embodiments, one or more semiconductor component (not shown) such as transistors, diodes, resistors, CMOS devices or the like may be disposed on the substrate 110 and fabricated by using manufacturing processes of front-end-of-the-line (FEOL) in a semiconductor manufacture field. The metal layers ML are fabricated by using manufacturing processes of back-end-of-the-line (BEOL) in the semiconductor manufacture field.

In some embodiments, the substrate 110 may be a silicon substrate or a semiconductor substrate formed of other semiconductor materials. For example, the material of the substrate 110 may include silicon, silicon germanium, silicon carbon, III-V compound semiconductor material, or the like. In some embodiments, the substrate 110 is lightly doped with a p-type impurity, but the present disclosure is not limited thereto. In some embodiments, the substrate 110 may include a silicon on insulator (SOI) structure. In details, the SOI structure may have a layer of a semiconductor material, such as silicon, formed on an insulator layer. The insulator layer may include a buried oxide (BOX) layer and/or a silicon oxide layer. It is noted that the substrate 110 may include another elementary semiconductor, such as germanium, a compound semiconductor including silicon carbide, gallium arsenic, gallium phosphide, indium phosphide, indium arsenide and indium antimonide, an alloy semiconductor including SiGe, GaAsP, AlInAs, AlGaAs, GaInAs, GaInP and GaInAsP, or combinations thereof. Additionally, other types of substrates, such as a multilayer substrate, a gradient substrate, or combinations thereof, may also be adopted.

In some embodiments, a portion of the metal layers ML may establish electrical transmission for the semiconductor component (not shown) formed on the substrate 110. In some embodiments, the metal layers ML over the substrate 110 may construct an electronic component structure such as a capacitor structure 102. For the sake of simplicity and clarity of the drawings, FIG. 1 only presents a portion of the capacitor structure 102. The electronic device 100 may further include vias VA that connect different layers of the metal layers ML to create the required electric transmission routes. In some embodiments, the metal layers ML and the vias VA may be formed by damascene process, dual-damascene process, combinations thereof, or the like. For example, a trench etching process may be conducted to form a plurality of trenches in an insulation layer of the insulation structure INS. Subsequently, a metallic material such as Cu, Al, Ag, Au, W, Mo, Ru, Co, Ni, Pd, Pt, other metals or their alloys may be provided in the trenches as a medium for electrical transmission. In some embodiments, a planarization process may be conducted to remove exceeded metallic material over the trench so that the metal layers ML are formed in the prescribed patterns embedded in the insulation structure INS. The capacitor structure 102 may be built by the metal layers ML and the vias VA by using manufacturing processes compatible to BEOL in the semiconductor manufacture field, such as the damascene process, dual-damascene process, combinations thereof, or the like.

The capacitor structure 102 at least includes electrode metal layers 120˜140 and an underlying metal layer 150. In some embodiments, the electrode metal layers 120˜140 are an i^{th} layer to an j^{th} layer of the metal layers ML and the underlying metal layer 150 is the (i−1)^{th} layer of the metal layers ML, wherein j>i, and i is greater than 2. In some embodiments, i is 3, such that the electrode metal layer 120 may be the third metal layer of the metal layers ML, the electrode metal layer 130 may be the fourth metal layer of the metal layers ML, the electrode metal layer 140 may be the fifth metal layer of the metal layers ML, and the underlying metal layer 150 may be the second metal layer of the metal layers ML. The electrode metal layers 120˜140 are considered as the layers of the metal layers ML forming the capacitor electrodes of the capacitor structure 102 and the underlying metal layer 150 is one layer of the metal layers ML more adjacent to the substrate 110 than the electrode metal layers 120˜140.

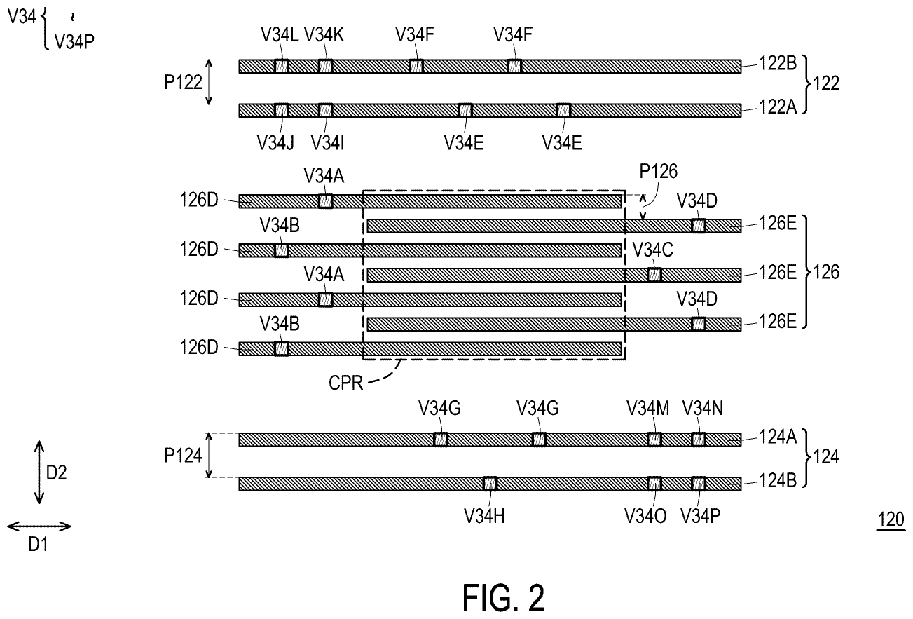

In some embodiments, each of the electrode metal layers 120˜140 includes bus lines, opposite bus lines and finger electrodes arranged in parallel between the bus lines and the opposite bus lines, and the finger electrodes are served as the capacitor electrodes of the capacitor structure 102. For example, FIG. 2 schematically illustrates an i^{th} layer of the metal layers forming the capacitor structure in accordance with some embodiments of the disclosure. Referring to FIG. 1 and FIG. 2, the electrode metal layer 120, i.e. the i^{th} (third) layer of the metal layers ML, includes bus lines 122, opposite bus lines 124 and finger electrodes 126 arranged in parallel between the bus lines 122 and the opposite bus lines 124. The bus lines 122, the opposite bus lines 124 and the finger electrodes 126 are substantially arranged in parallel to each other and each extends in a direction D1. The finger electrodes 126 includes odd electrodes 126D and even electrodes 126E alternately arranged in a direction D2 that is intersected with or perpendicular to the direction D1. In some embodiments, the odd electrodes 126D and the even electrodes 126E of the finger electrodes 126 are arranged side-by side in a coupling region CPR, the odd electrodes 126D extend exceeding the even electrodes 126E at a side of the coupling region CPR along the direction D1, and the even electrodes 126E extend exceeding the odd electrodes 126D at an opposite side of the coupling region CPR along the direction D1. A portion of each of the odd electrodes 126D exceeding the even electrodes 126E is next to a portion of another one of the odd electrodes 126D exceeding the even electrodes 126E without a metal feature of the electrode metal layer 120 interposed therebetween. Similarly, a portion of each of the even electrodes 126E exceeding the odd electrode 126D is next to a portion of another one of the even electrodes 126E exceeding the odd electrode 126D without a metal feature of the electrode metal layer 120 interposed therebetween.

In some embodiments, the odd electrodes 126D of the finger electrodes 126 are configured to receive or connected to a different voltage from the even electrodes 126E of the finger electrodes 126. The odd electrodes 126D and the even electrode 126E arranged side-by side and alternately within the coupling region CPR may cause the capacitance coupling effect that contributes the capacitance of the capacitor structure 102. In some embodiments, the linewidths of the finger electrodes 126 may be identical to each other and the finger electrodes 126 may be arranged in a constant pitch. The linewidths of the finger electrodes 126 and the pitch of the finger electrodes 126 may be determined based on the required characters of the capacitor structure 102. Herein, seven finger electrodes 126 are presented in the drawings, but the numbers of the figure electrodes 126 may be determined based on the required characters of the capacitor structure 102 without being limited to the structure shown in the drawings of the disclosure since the drawings are intended to schematically present the arrangements and the disposition relationships of respective features in an easy and clear way. In addition, the terms “odd” and “even” are used for distinguish two adjacent features among the features arranged in sequence, an “odd” feature may be considered as an “even feature” if the features are counted in a different direction. For example, in the case of even numbers of features arranged in sequence along the direction D1, the outer most one at the right side is considered as the “odd” feature and the outer most one at the left side is considered as the “even” feature when counting from the right side, while the outer most one at the right side is considered as the “even” feature and the outer most one at the left side is considered as the “odd”feature when counting from the left side.

In some embodiments, two bus lines 122 and two opposite bus lines 124 are disposed at opposite sides of the finger electrodes 126. Specifically, the bus lines 122 include the first bus line 122A and the second bus line 122B further from the finger electrodes 126 than the first bus line 122A, and similarly, the opposite bus lines 124 include the first opposite bus line 124A and the second opposite bus line 124B further from the finger electrodes 126 than the first opposite bus line 124A. In some embodiments, the first bus line 122A and the second bus line 122B may be arranged in a pitch greater than the finger electrodes 126 and the first opposite bus line 124A and the second opposite bus line 124B may be also arranged in a pitch greater than the finger electrodes 126. For example, in some embodiments, the pitch P126 of the finger electrodes 126 is smaller than the pitch P122 of the bus lines 122 and smaller than the pitch P124 of the opposite bus lines 124 as well, but the disclosure is not limited thereto.

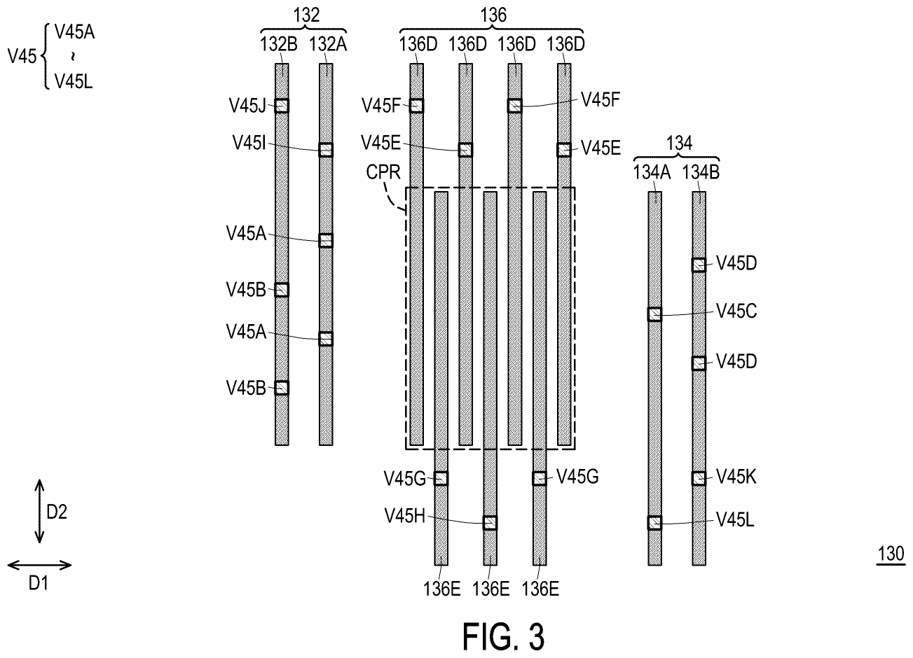

FIG. 3 schematically illustrates the (i+1)^{th} layer of the metal layers forming the capacitor structure in accordance with some embodiments of the disclosure. Referring to FIG. 1 and FIG. 3, the electrode metal layer 130, i.e. the (i+1)^{th} (fourth) layer of the metal layers ML, includes bus lines 132, opposite bus lines 134 and finger electrodes 136 arranged in parallel between the bus lines 132 and the opposite bus lines 134. The electrode metal layer 130 may have a similar design as the electrode metal layer 120, but the metal features in the electrode metal layer 130 extend in a direction D2 intersecting the extending direction (the direction D1) of the metal features in the electrode metal layer 120. Specifically, the bus lines 132, the opposite bus lines 134 and the finger electrodes 136 are metal features with an elongated shape along the second direction D2 intersecting the extending direction (the direction D1) of the bus lines 122, the opposite bus lines 124 and the finger electrodes 126 in the electrode metal layer 120.

The electrode metal layer 130 includes two bus lines 132 that are the first bus line 132A and the second bus line 132B further from the finger electrodes 136 than the first bus line 132A. The electrode metal layer 130 includes two opposite bus lines 134 that are the first opposite bus line 134A and the second opposite bus line 134B further from the finger electrodes 136 than the first opposite bus line 134A. The finger electrodes 136 arranged between the bus lines 132 and the opposite bus lines 134 may be divided in to odd electrodes 136D and even electrodes 136E alternately arranged along the direction D1. The odd electrodes 136D and the even electrodes 136E are arranged side-by-side within the coupling region CPR. The odd electrodes 136D extend exceeding the even electrodes 136E at a side of the coupling region CPR along the direction D2 and the even electrodes 136E extend exceeding the odd electrodes 136D at an opposite side of the coupling region CPR along the direction D2. In some embodiments, no metal feature of the electrode metal layer 130 is interposed between a portion of each of the odd electrodes 136D exceeding the even electrodes 136E and a portion of another one of the odd electrodes 136D exceeding the even electrodes 136E and no metal feature of the electrode metal layer 130 is interposed between a portion of each of the even electrodes 136E exceeding the odd electrode 136D and a portion of another one of the even electrodes 136E exceeding the odd electrode 136D.

In some embodiments, the capacitor structure 102 further includes interlayer vias V34 shown in FIGS. 1 and 2 and the interlayer vias V34 are the vias VA extending between the electrode metal layer 120 (the 3^{rd} metal layer of the metal layers ML) and the electrode metal layer 130 (the 4^{th} metal layer of the metal layers ML) to connect the metal features in the two metal layers ML. In some embodiments, a portion of each of the even electrodes 126E exceeding the odd electrode 126D crosses the bus lines 134 in the electrode metal layer 130 and a portion of each of the odd electrodes 126D exceeding the even electrodes 126E crosses the opposite bus lines 132 in the electrode metal layer 130. The portion of each of the odd electrodes 126D exceeding the even electrode 126E crosses both the first bus line 132A and the second bus line 132B in the electrode metal layer 130 and is connected to a single one of the first bus line 132A and the second bus line 132B through one corresponding interlayer via V34. In addition, the interlayer vias V34 connected between the odd electrodes 126D and the bus lines 132 are arranged in a zig-zag path. Similarly, the portion of each of the even electrodes 126E exceeding the odd electrode 126D overlaps both the first opposite bus line 134A and the second opposite bus line 134B in the electrode metal layer 130 and is connected to a single one of the first opposite bus line 134A and the second opposite bus line 134B through one corresponding interlayer via V34. The interlayer vias V34 connected between the even electrodes 126E and the opposite bus lines 134 are arranged in a zig-zag path.

For example, FIG. 2 shows four odd electrodes 126D, when counting in a direction from the bus lines 122 toward the opposite bus lines 124, the first odd electrode 126D as well as the third odd electrode 126D are connected to the first bus line 132A through corresponding interlayer vias V34A, and the second odd electrode 126D and the fourth odd electrode 126D are connected to the second bus line 132B through corresponding interlayer vias V34B. The interlayer vias V34B are positioned further from the couple region CPR than the interlayer vias V34A. The interlayer vias V34A are arranged along the first bus line 132A and the interlayer vias V34B are arranged along the second bus line 132B. Therefore, the odd electrodes 126D are alternately connected to the first bus line 132A and the second bus line 132B through corresponding interlayer vias V34A and V34B, respectively.

FIG. 2 shows three even electrodes 126E, the middle even electrode 126E is connected to the first opposite bus line 134A in the electrode metal layer 130 through the interlayer via V34C, and the first and the third even electrodes 126E are connected to the second opposite bus line 134B through the interlayer vias V34D. The interlayer vias V34D are positioned further from the couple region CPR than the interlayer vias V34C and the interlayer vias V34D are arranged along the opposite bus line 134B. Therefore, the even electrodes 126E are alternately connected to the first opposite bus line 134A and the second opposite bus line 134B through corresponding interlayer vias V34C and V34D, respectively.

Referring to FIGS. 2 and 3, the bus lines 132, the opposite bus lines 134 and the finger electrodes 136 in the electrode metal layers 130 are connected to the bus lines 122 and the opposite bus lines 124 in the electrode metal layers 120 through corresponding interlayer vias V34. For example, the odd electrodes 136D of the finger electrodes 136 are alternately connected to the first bus line 122A and the second bus line 122B through the interlayer vias V34E and V34F, respectively, and the even electrodes 136E of the finger electrodes 136 are alternately connected to the first opposite bus line 124A and the second opposite bus line 124B through the interlayer vias V34G and V34H, respectively.

In some embodiments, when counting in a direction from the bus lines 132 toward the opposite bus lines 134, the first odd electrode 136D of the finger electrodes 136 and the third odd electrode 136D of the finger electrodes 136 are connected to the second bus line 122B in the electrode metal layer 122 through the interlayer vias V34F and the second odd electrode 136D of the finger electrodes 136 and the fourth odd electrode 136D of the finger electrodes 136 are connected to the first bus line 122A in the electrode metal layer 122 through the interlayer vias V34E. Namely, the interlayer vias V34E are connected to the first bus line 122A and the interlayer vias V34F are connected to the second bus line 122B. Similarly, when counting in a direction from the bus lines 132 toward the opposite bus lines 134, the first even electrode 136E of the finger electrode 136 and the third even electrode 136E of the finger electrodes 136 are connected to the first opposite bus line 124A through the interlayer via V34G and the middle (second) even electrode 136E of the finger electrodes 136 is connected to the second opposite bus line 124B through the interlayer via V34H.

The first bus line 122A and the second bus line 122B in the electrode metal layer 120 extend in the direction D1 for a certain length to cross both the first bus line 132A and the second bus line 132B in the electrode metal layer 130. The first bus line 122A in the electrode metal layer 120 is connected to the first bus line 132A in the electrode metal layer 130 through the interlayer via V34I, and connected to the second bus line 132B through the interlayer via V34J. The second bus line 122B in the electrode metal layer 120 is connected to the first bus line 132A in the electrode metal layer 130 through the interlayer via V34K and connected to the second bus line 132B in the electrode metal layer 130 through the interlayer via V34L. Accordingly the bus lines 122 in the electrode metal layer 120 are electrically connected to the bus lines 132 in the electrode metal layer 130.

The first opposite bus line 124A and the second opposite bus line 124B in the electrode metal layer 120 extend in the direction D1 for a certain length to cross both the first opposite bus line 134A and the second opposite bus line 134B in the electrode metal layer 130. The first opposite bus line 124A in the electrode metal layer 120 is connected to the first opposite bus line 134A in the electrode metal layer 130 through the interlayer via V34M, and connected to the second opposite bus line 134B through the interlayer via V34N. The second opposite bus line 124B in the electrode metal layer 120 is connected to the first opposite bus line 134A in the electrode metal layer 130 through the interlayer via V34O and connected to the second opposite bus line 134B in the electrode metal layer 130 through the interlayer via V34P. Accordingly the opposite bus lines 124 in the electrode metal layer 120 are electrically connected to the opposite bus lines 134 in the electrode metal layer 130.

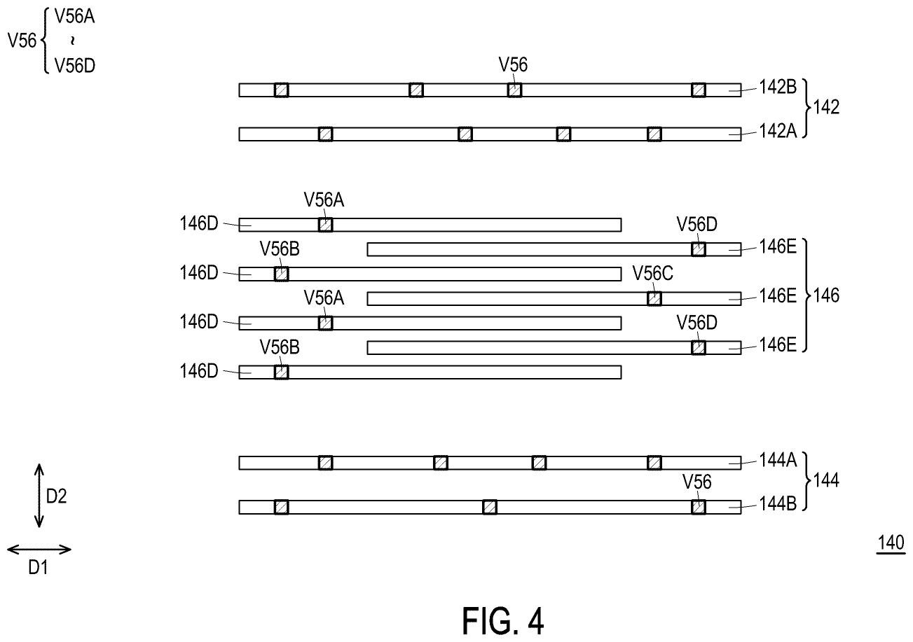

FIG. 4 schematically illustrates the j^{th} layer of the metal layers forming the capacitor structure in accordance with some embodiments of the disclosure. Referring to FIG. 1 and FIG. 4, the electrode metal layer 140, i.e. the j^{th} (fifth) layer of the metal layers ML, includes bus lines 142, opposite bus lines 144 and finger electrodes 146 arranged in parallel between the bus lines 142 and the opposite bus lines 144. The electrode metal layer 140 may have a similar design as the electrode metal layer 120, but the disclosure is not limited thereto. For example, in some embodiments, the quantity of the finger electrodes 146 in the electrode metal layer 140 may be different from the finger electrodes 126 in the electrode metal layer 120. The metal features such as the bus lines 142, the opposite bus lines 144 and the finger electrodes 146 in the electrode metal layer 140 have elongated shapes along the direction D1. In some embodiments, the bus lines 142 in the electrode metal layer 140 may overlap the bus lines 122 in the electrode metal layer 120, the opposite bus lines 144 in the electrode metal layer 140 may overlap the opposite bus lines 124 in the electrode metal layer 120, and the finger electrodes 146 in the electrode metal layer 140 may overlap the finger electrodes 126 in the electrode metal layer 120.

The electrode metal layer 140 includes two bus lines 142 that are the first bus line 142A and the second bus lines 142B and two opposite bus lines 144 that are the first opposite bus line 144A and the second opposite bus line 144B. The capacitor structure 102 further includes interlayer visa V45 shown in FIGS. 1 and 3 and the interlayer vias V45 are the vias VA extending between the electrode metal layer 130 (the 4^{th} metal layer of the metal layers ML) and the electrode metal layer 140 (the 5^{th} metal layer of the metal layers ML) to connect the metal features in the two metal layers ML.

Referring to FIGS. 3 and 4, odd electrodes 146D of the finger electrodes 146 may be alternately connected to the first bus line 132A and the second bus line 132B though corresponding interlayer vias V45A and V45B, respectively. For example, when counting in a direction from the bus lines 142 towards the opposite bus lines 144, the first odd electrode 146D and the third odd electrode 146D in the electrode metal layer 140 are connected to the first bus line 132A in the electrode metal layer 130 through respective interlayer vias V45A, and the second odd electrode 146D and the fourth odd electrode 146D in the electrode metal layer 146 are connected to the second bus line 132B in the electrode metal layer 132 through the interlayer vias V45B. The interlayer vias V45A and the interlayer vias V45B are arranged in a zig-zag path. In addition, the middle (second) even electrode 146E of the finger electrodes 146E in the electrode metal layer 140 is connected to the first opposite bus line 134A through the interlayer via V45C and the first and the third even electrodes 146E of the finger electrodes 146 in the electrode metal layer 140 are connected to the second opposite bus line 134B through the interlayer vias V45D. The interlayer vias V45C and the interlayer vias V45D are arranged in a zig-zag path.

The finger electrodes 136 in the electrode metal layer 130 are also connected to the bus lines 142 and the opposite bus lines 144 in the electrode metal layer 140 through the interlayer vias V45. For example, when counting in a direction from the bus lines 132 towards the opposite bus lines 134, the second and the fourth odd electrodes 136D of the finger electrodes 136 in the electrode metal layer 130 are connected to the first bus line 142A in the electrode metal layer 140 through the interlayer vias V45E and the first and the third odd electrodes 136D of the finger electrode 136 in the electrode metal layer 130 are connected to the second bus line 142B in the electrode metal layer 140 through the interlayer vias V45F. The interlayer vias V45E and the interlayer vias V45F are arranged in a zig-zag path. Simultaneously, the first and the third even electrodes 136E of the finger electrodes 136 in the electrode metal layer 130 are connected to the firs opposite bus line 144A in the electrode metal layer 140 through the interlayer vias V45G and the middle (second) even electrode 136E of the finger electrodes 136 in the electrode metal layer 130 is connected to the second opposite bus line 144B through the interlayer via V45H. The interlayer vias V45G and the interlayer vias V45H are arranged in a zig-zag path.

In addition, each of the first bus line 132A and the second bus line 132B in the electrode metal layer 130 overlaps both the first bus line 142A and the second bus line 142B in the electrode metal layer 140, and is connected to a single one of the first bus line 142A and the second bus line 142B in the electrode metal layer 140. Similarly, each of the first opposite bus line 134A and the second opposite bus line 134B in the electrode metal layer 130 overlaps both the first opposite bus line 144A and the second opposite bus line 144B in the electrode metal layer 140, and is connected to a single one of the first opposite bus line 144A and the second opposite bus line 144B in the electrode metal layer 140. For example, the first bus line 132A in the electrode metal layer 130 is connected to the first bus line 142A in the electrode metal layer 140 through the interlayer via V45I, the second bus line 132B in the electrode metal layer 130 is connected to the second bus line 142B in the electrode metal layer 140 through the interlayer via V45J, the first opposite bus line 134A in the electrode metal layer 130 is connected to the second opposite bus line 144B in the electrode metal layer 140 through the interlayer via V45L, and the second opposite bus line 134B in the electrode metal layer 130 is connected to the first opposite bus line 144A through the interlayer vias V45K. In some embodiments, the arrangement of the interlayer vias V45 may be modified to connect the bus lines 132 to the bus lines 142 and/or connect the opposite bus lines 134 to the opposite bus lines 144 based on various design requirements. In addition, the bus lines 122 in the electrode metal layer 120, the bus lines 132 in the electrode metal layer 130 and the bus lines 142 in the electrode metal layer 140 are electrically connected through the corresponding interlayer vias V34 and V45 and the opposite bus lines 124 in the electrode metal layer 120, the opposite bus lines 134 in the electrode metal layer 130 and the opposite bus lines 144 in the electrode metal layer 140 are electrically connected through the corresponding interlayer vias V34 and V45

In some embodiments, the electronic device 100 in FIG. 1 includes further metal layer ML over the electrode metal layer 140 to form the capacitor structure 102 and the capacitor structure 102 may further includes interlayer vias V56 shown in FIG. 4 to connect the metal features in the electrode metal layer 140 to conductive feature in a higher layer. As shown in FIG. 4, the interlayer vias V56A and the interlayer vias V56B are arranged in a zig-zag path to connect the odd electrodes 146D of the finger electrodes 146 to the conductive features in the higher layer and the interlayer vias V56C and the interlayer vias V56D are arranged in a zig-zag path to connect the even electrodes 146E of the finger electrodes 146 to the conductive features in the higher layer. Each of the odd electrodes 146D and the even electrodes 146E is connected to the conductive features in the higher layer though a single one of the interlayer vias V56.

In some embodiments, the capacitance of the capacitor structure 102 is contributed by the finger electrodes (including the finger electrodes 126, 136 and 146 and other finger electrode in higher layer) formed in the metal layers ML. The finger electrodes 136 formed in the electrode metal layer 130 are connected to the bus lines 122 and the opposite bus lines 124 in the lower electrode metal layer 120 through the interlayer vias V34 and further connected to the bus lines 142 and the opposite bus lines 144 in the upper electrode metal layer 140 through the interlayer vias V45. The finger electrodes 146 formed in the electrode metal layer 140 are connected to the bus lines 152 and the opposite bus lines 154 in the lower electrode metal layer 130 through the interlayer vias V45 and also connected to the conductive features in the higher metal layer (not shown) through the interlayer vias V56. Therefore, each of the finger electrodes 136 in the electrode metal layer 130 and the finger electrodes 146 in the electrode metal layer 140 is connected to both the upper layer bus line and the lower layer bus line.

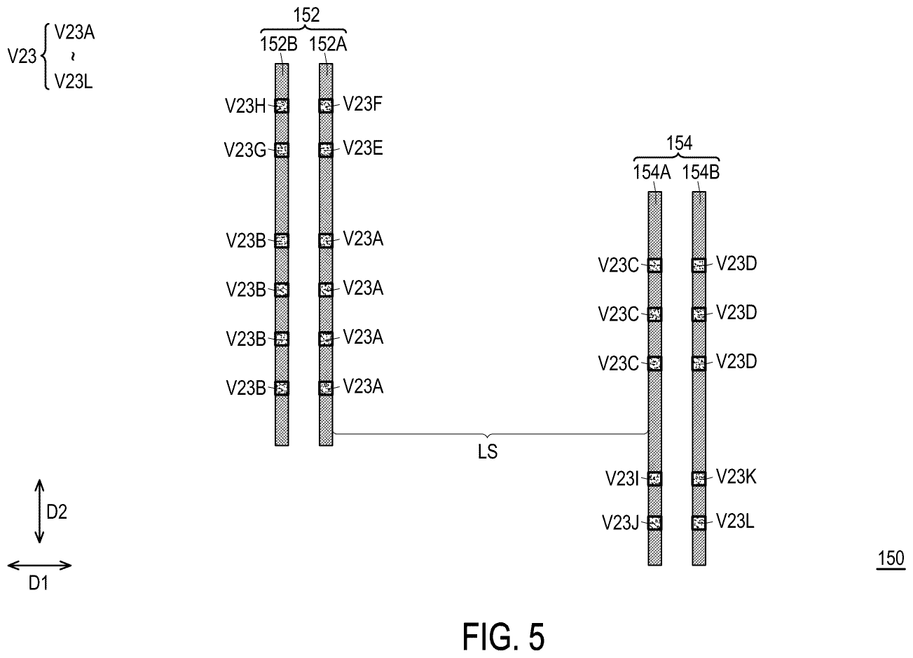

In some embodiments, as shown in FIG. 1, the capacitor structure 102 may further include an underlying layer 150 under the electrode metal layer 120 that is the bottom most layer of the electrode metal layers 120˜140. FIG. 5 schematically illustrates the underlying metal layer of the capacitor structure in accordance with some embodiments of the disclosure. Referring to FIGS. 1 and 5, the underlying metal layer 150 is the (i−1)^{th} layer of the metal layers ML in the electronic device 100. The underlying metal layer 150 may include one or more bus line and one or more opposite bus line. In the example shown in FIG. 5, the underlying metal layer 150 includes two underlying bus lines 152 and two opposite underlying bus lines 154. For descriptive purpose, the two underlying bus lines 152 are respectively named as the first underlying bus line 152A and the second underlying bus line 152B and the two opposite underlying bus lines 154 respectively named as the first opposite underlying bus line 154A and the second opposite underlying bus line 154B.

Referring to FIGS. 1, 2 and 5, the underlying bus lines 152 and the opposite underlying bus lines 154 in the underlying metal layer 150 extend in the direction D2 intersecting the extending direction of the finger electrodes 126 in the electrode metal layer 120 and the underlying bus lines 152 is laterally spaced from the opposite underlying bus lines 154 in the direction D1. In some embodiments, no conductive features in the underlying metal layer 150 is interposed between the underlying bus lines 152 and the opposite underlying bus lines 154 and the insulation structure INS fills in the lateral spacing LS between the underlying bus lines 152 and the opposite underlying bus lines 154. Therefore, the finger electrodes 126 in the electrode metal layer 120 (i.e. the i^{th} metal layer of the metal layers ML) are the finger electrodes in the bottom most layer of the electrode metal layers, and the bottom most capacitor electrodes of the capacitor structure 102. In some embodiments, there is no capacitor electrode formed in the underlying metal layer 150, but the disclosure is not limited thereto.

In some embodiments, the odd electrodes 126D of the finger electrodes 126 in the electrode metal layer 120 extend exceeding the even electrodes 126E in the direction D1 may cross the underlying bus lines 152 in the underlying metal layer 150 in the plane view. Similarly, the even electrodes 126E of the finger electrodes 126 in the electrode metal layer 120 extend exceeding the odd electrodes 126D in the direction D1 may cross the opposite underlying bus lines 154 in the underlying metal layer 150 in the plane view. In addition, the capacitor structure 102 further includes underlying conductive vias V23 that are the vias VA extending between the underlying metal layer 150 (the (i−1)^{th} (2^{nd}) metal layer of the metal layers ML) and the electrode metal layer 120 (the 3^{rd} metal layer of the metal layers ML) to connect the finger electrodes 126 in the bottom most layer of the electrode metal layers (the electrode metal layer 120) to the underlying bus lines 152/the opposite underlying bus lines 154 in the underlying metal layer 150.

In some embodiments, all of the odd electrodes 126D of the finger electrodes 126 in the electrode metal layer 126 (the bottom most layer of the electrode metal layers in the capacitor structure 102) are connected to the first underlying bus line 152A through the underlying vias V23A and further connected to the second underlying bus line 152B through the underlying vias V23B. Therefore, all of the odd electrodes 126D of the finger electrodes 126 are connected to one bus line in the upper layer (i.e. the electrode metal layer 130) and two bus lines in the lower layer (i.e. the underlying layer 150), which helps to reduce the resistance of the capacitor structure 102 and is beneficial to the Q factor (quality factor) of the capacitor structure 102.

The even electrodes 126E of the finger electrodes 126 in the electrode metal layer 126 (the bottom most layer of the electrode metal layers in the capacitor structure 102) are all connected to both the first opposite underlying bus line 154A and the second opposite underlying bus line 154B through the underlying vias V23C and V23D, respectively. All of the even electrodes 126E of the finger electrodes 126 are connected to one bus line in the upper layer (i.e. the electrode metal layer 130) and two bus lines in the lower layer (i.e. the underlying layer 150), which helps to reduce the resistance of the capacitor structure 102 and is beneficial to the Q factor (quality factor) of the capacitor structure 102.

In addition, the first underlying bus line 152A is connected to first bus line 122A in the electrode metal layer 120 through the underlying via V23E and connected to the second bus line 122B in the electrode metal layer 120 through the underlying via V23F. The second underlying bus line 152B is connected to the first bus line 122A in the electrode metal 120 through the underlying via V23G and connected to the second bus line 122B through the underlying via V23H. The first opposite underlying bus line 154A is connected to the first opposite bus line 124A in the electrode metal layer 120 through the underlying via V23I and connected to the second opposite bus line 124B through the underlying via V23J. The second opposite underlying bus line 154B is connected to the first opposite bus line 124A in the electrode metal layer 120 through the underlying via V23K and connected to the second opposite bus line 124B in the electrode metal layer 120 through the underlying via V23L. Therefore, the bus lines 152 in the underlying metal layer 150 are electrically connected to the bus lines 122 in the electrode metal layer 120, the bus lines 132 in the electrode metal layer 130 and the bus lines 142 in the electrode metal layer 140 and the opposite underlying bus lines 154 in the underlying metal layer 150 are electrically connected to the opposite bus lines 124 in the electrode metal layer 120, the opposite bus lines 134 in the electrode metal layer 130, and the opposite bus lines 144 in the electrode metal layer 140.

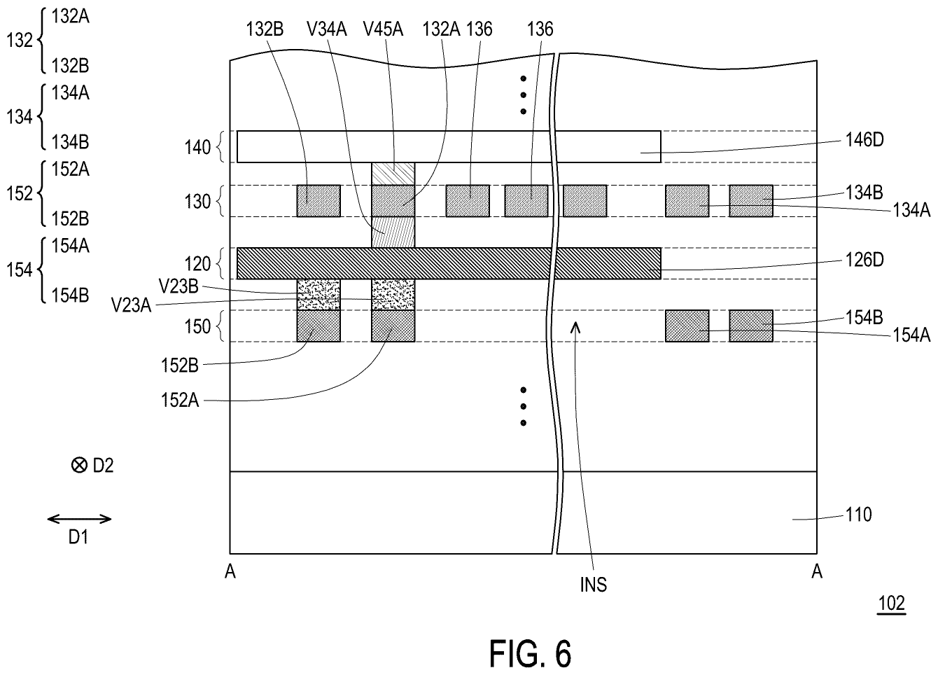

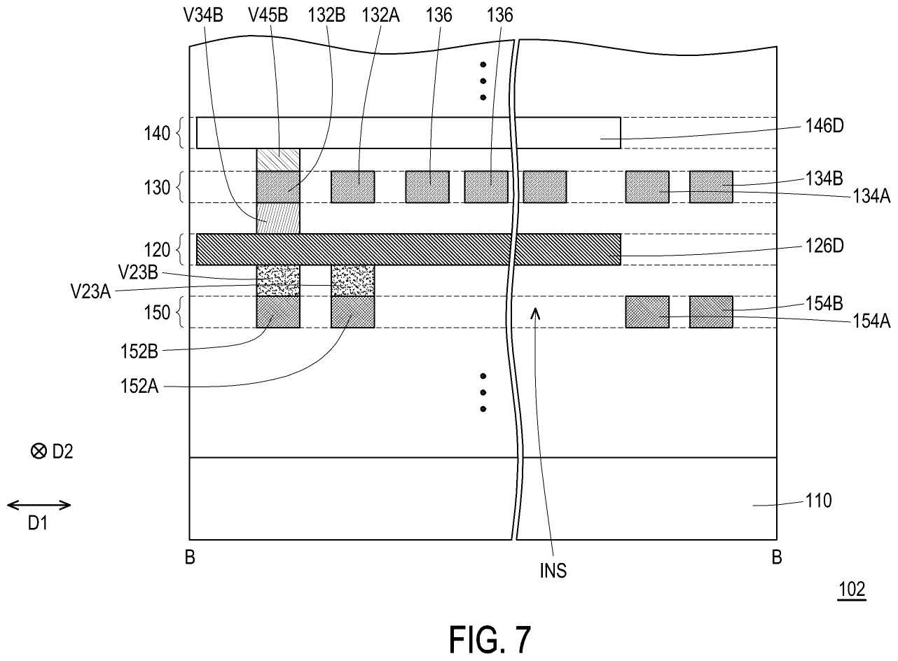

FIGS. 6-8 schematically illustrate respective cross sections of the capacitor structure taken along lines A-A, B-B and C-C in FIG. 1, respectively. Specifically, the lines A-A and B-B extend along two adjacent odd electrodes 146D of the finger electrodes 146 in the electrode metal layer 140 and the line C-C extends along the second opposite bus line 144B in the electrode metal layer 140. As shown in FIGS. 6 and 7, the odd electrode 146D of the finger electrodes 146 in the electrode metal layer 140 and the odd electrode 126D of the finger electrodes 126 in the electrode metal layer 120 extend in the same direction D1 and are overlapped with each other. The bus lines 132, the opposite bus lines 134 and the finger electrodes 136 in the electrode metal layer 130 extend along the direction D2 intersected with the direction D1. The underlying bus lines 152 and the opposite underlying bus lines 154 in the underlying metal layer 150 extend in the same direction, i.e. the direction D2 and overlapped with bus lines 132 and the opposite bus lines 134, respectively.

The odd electrode 126D of the electrode metal layer 120 shown in FIG. 6 is connected to the first bus line 132A in the upper layer (the electrode metal layer 130) and connected to both bus lines 152 in the lower layer (the underlying metal layer 150). In some embodiments, the underlying via V23A, the interlayer via V34A and the interlayer via V45A are overlapped to connect the first underlying bus line 152A in the underlying metal layer 150, one of the odd electrodes 126D in the electrode metal layer 120, the first bus line 132A in the electrode metal layer 130 and one of the odd electrode 146D in the electrode metal layer 140 to form a continuous metal path.

The odd electrode 126D of the electrode metal layer 120 shown in FIG. 7 is connected to the second bus line 132B in the upper layer (the electrode metal layer 130) and connected to both bus lines 152 in the lower layer (the underlying metal layer 150). In some embodiments, the underlying via V23B, the interlayer via V34B and the interlayer via V45B are overlapped to connect the second underlying bus line 152B in the underlying metal layer 150, one of the odd electrodes 126D in the electrode metal layer 120, the second bus line 132B in the electrode metal layer 130 and one of the odd electrode 146D in the electrode metal layer 140 to form a continuous metal path.

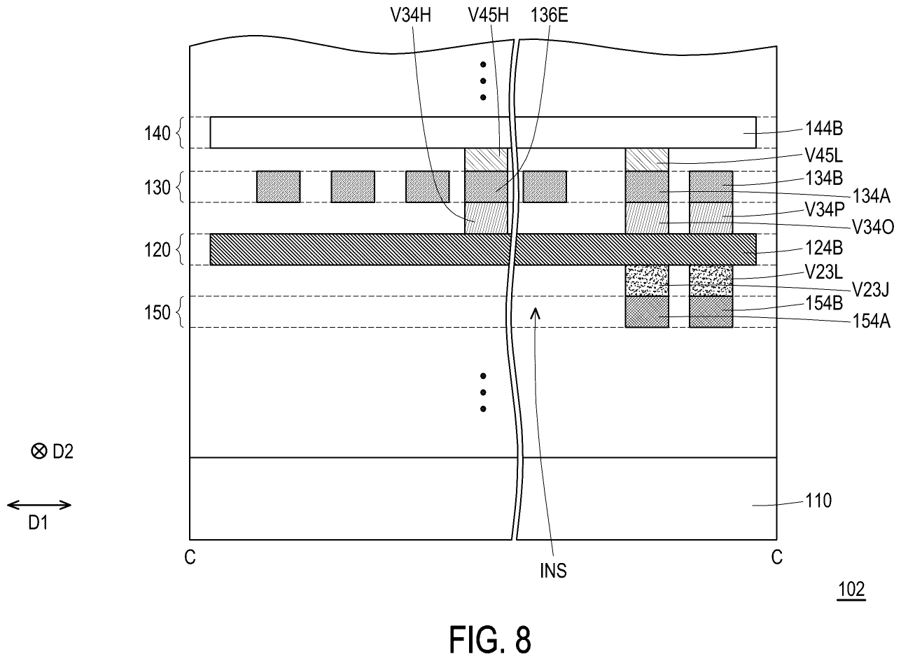

In FIG. 8, the underlying via V23J, the interlayer via V34O and the interlayer via V45L are overlapped to connect the first opposite underlying bus line 154A in the underlying layer 150, the second opposite bus line 124B in the electrode metal layer 120, the first opposite bus line 134A in the electrode metal layer 130 and the second opposite bus line 144B in the electrode metal layer 140 to form a continuous metal path. The underlying via V23L and the interlaying via V34P are overlapped to connect the second opposite underlying bus line 154B in the underlying metal layer 150, the second opposite bus line 124B of the electrode metal layer 120 and the second opposite bus line 134B in the electrode metal layer 130 to form a continuous metal path. In addition, the interlayer via V34H and the interlayer via V45H are overlapped to connect the second opposite bus line 124B in the electrode metal layer 120, the even electrode 136E in the electrode metal layer 130 and the second opposite bus line 144B to form a continuous metal.

In FIGS. 6 to 8, the space between the metal features are filled by the insulation structure INS. For example, as shown in FIGS. 6 and 7, the insulation structure INS continuously extends between the first underlying bus line 152A and the first opposite underlying bus line 154A. In addition, the bus lines, the opposite bus lines and the finger electrodes in the same electrode metal layer are spaced from one another by the insulation structure INS. In some embodiments, the insulation structure INS include oxide insulation material and the capacitor structure 102 may be considered as an MOM (metal-oxide-metal) capacitor structure. In some embodiments, the insulation structure INS and the metal features in the metal layers ML may be fabricated by using manufacturing processes of BEOL in the semiconductor manufacture field. In some embodiments, the insulation structure INS may include multiple insulation material layers that are formed with respective to the metal layers ML.

In some embodiments, referring to FIGS. 1 to 8, a method of fabricating an electronic device 100 may include sequentially forming metal layers ML on a substrate 110, wherein each layer of an i^{th} layer (120) to an j^{th} layer (140) of the metal layers ML includes bus lines (122, 132, 142), opposite bus lines (124, 134, 144) and finger electrodes (126, 136, 146) arranged in parallel between the bus lines (122, 132, 142) and the opposite bus lines (124, 134, 144), the finger electrodes (126, 136, 146) in two adjacent layers of the i^{th} layer to the j^{th} layer extend in different directions (D1 and D2 that are intersected or perpendicular to each other), an (i−1)^{th} layer of the metal layers (the underlying metal layer 150) includes an underlying bus line (152) and an opposite underlying bus line (154), j>i, and i is greater than 2; connecting odd electrodes (126D) of the finger electrodes (126) in the i^{th} layer of the metal layers (120) to the underlying bus line (152); connecting even electrodes (126E) of the finger electrodes (126) in the i^{th} layer of the metal layers (120) to the opposite underlying bus line (154); and filling an insulation structure (INK) in a lateral spacing between the underlying bus line (152) and the opposite underlying bus line (154). In some embodiments, no capacitor electrode is formed between the underlying bus line (152) and the opposite underlying bus line (154) of the (i−1)^{th} layer of the metal layers (the underlying metal layer 150).

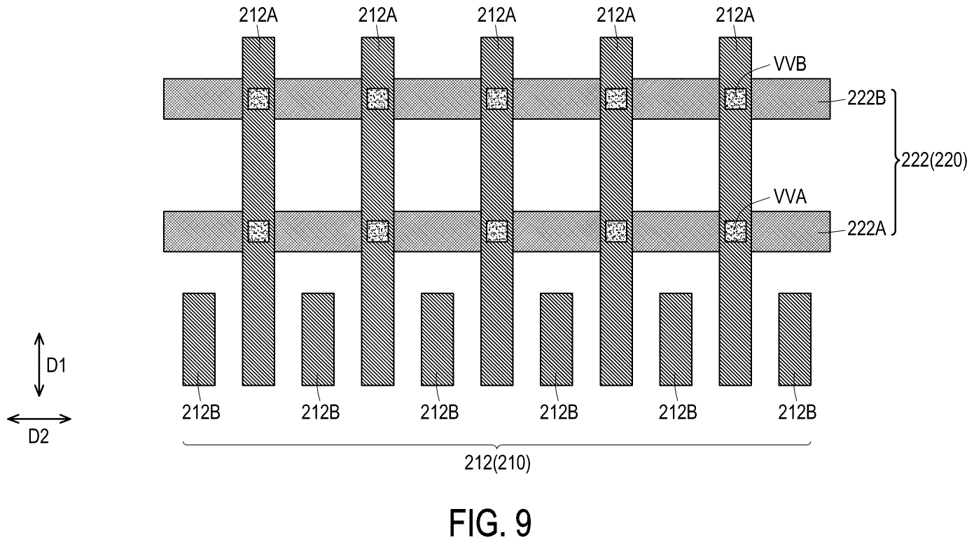

FIGS. 9-14 schematically illustrate the connection between the finger electrodes in the bottom most layer of the electrode metal layers and the underlying metal layer in accordance with some embodiments of the disclosure. The structures shown in FIGS. 9-14 are applicable to the capacitor structure 102 in FIG. 1 and serve as various embodiments for implementing the electrode metal layer 120, the underlying metal layer 150 and the underlying vias V23. Referring to FIG. 9, an electrode metal layer 210 and an underlying metal layer 220 may be considered as an implemental example of the electrode metal layer 120 and the underlying metal layer 150 shown in the previous embodiment. The electrode metal layer 210 includes finger electrodes 212 arranged in parallel to each other and each of the finger electrodes 212 extends in a direction D1 and the underlying metal layer 220 includes two bus lines 222 each extends in a direction D2 intersecting with the direction D1.

In FIG. 9, two adjacent finger electrodes 212 are respectively indicated as the electrode 212A and the electrode 212B. In some embodiments, the electrode 212A may be considered as an implemental example of one of the odd electrode 122D and the even electrode 122E and the electrode 212B may be considered as an implemental example of the other of the odd electrode 122D and the even electrode 122E. The electrode 212A extends exceeding the electrode 212B in the direction D1 and crosses the bus lines 222 while the electrodes 212B are spaced from the bus lines 222 in the direction D1. The two bus lines 222 are respectively indicated as the first bus line 222A and the second bus line 222B that is further from the electrodes 212B than the first bus line 222A. In some embodiments, the bus lines 222 may be considered as an implemental example of the underlying bus lines 152 or the opposite underlying bus lines 154 in the previous embodiment. The bus line 222A is connected to each of the electrodes 212A through a via VVA extending between the electrode metal layer 210 and the underlying metal layer 220 such that all of the electrodes 212A are connected to the bus line 222A. The bus line 222B is connected to each of the electrodes 212A through a via VVB extending between the electrode metal layer 210 and the underlying metal layer 220 such that all of the electrodes 212A are connected to the bus line 222B. In addition, every electrode 212A is connected to both the bus line 222A and the bus line 222B through corresponding vias VVA and VVB.

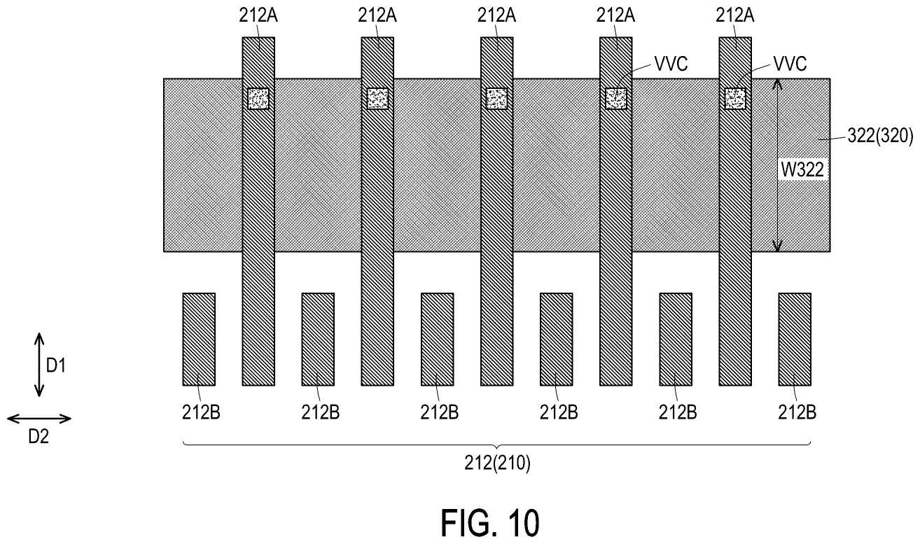

Referring to FIG. 10, an electrode metal layer 210 and an underlying metal layer 320 may be considered as an implemental example of the electrode metal layer 120 and the underlying metal layer 150 shown in the previous embodiment. The electrode metal layer 210 is substantially similar to the electrode metal layer 210 depicted in FIG. 9 and includes finger electrodes 212 each extending in the direction D1, wherein two adjacent finger electrodes 212 are respectively indicated as the electrode 212A and the electrode 212B. In FIG. 10, the underlying metal layer 320 includes one bus line 322 that extends in the direction D2, is connected to all of the electrodes 212A, and spaced from the electrodes 212B in the direction D1. The electrodes 212A are connected to the bus line 322 through the vias VVC that extend between the electrode metal layer 210 and the underlying metal layer 320 and the vias VVC are arranged in a linear path along the direction D2. In some embodiments, the bus line 322 has a width W322 measured in the direction D1 much greater than the dimension of each via VVC measured in the direction D1. In some embodiments, the bus line 322 in the underlying metal layer 320 has a width W322 greater than the bus lines and the opposite bus lines in the electrode metal layers 120-140 shown in the embodiments of FIGS. 1 to 5.

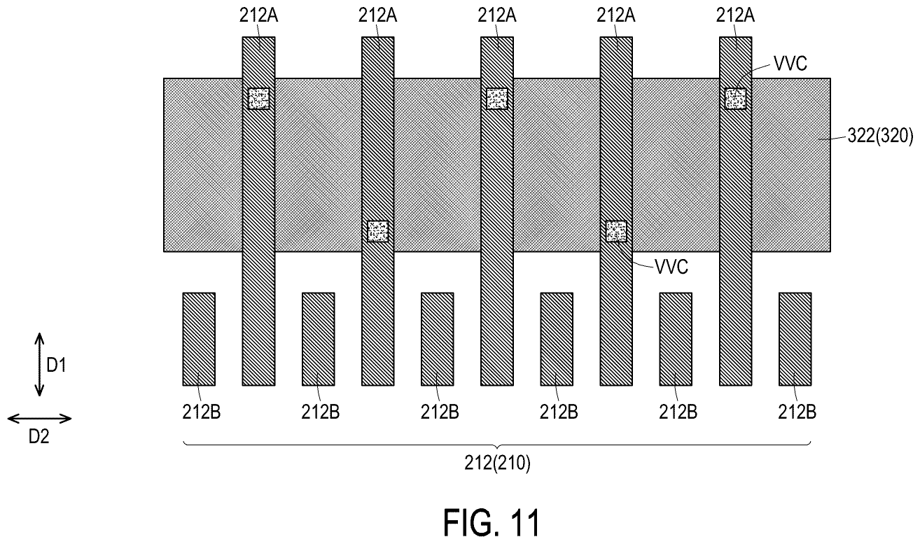

Referring to FIG. 11, an electrode metal layer 210 and an underlying metal layer 320 may be considered as an implemental example of the electrode metal layer 120 and the underlying metal layer 150 shown in the previous embodiment. The electrode metal layer 210 and the underlying metal layer 320 are substantially similar to the same component depicted in FIG. 10 and thus the descriptions for the electrode metal layer 210 and the underlying metal layer 320 in FIG. 10 are applicable to the embodiment of FIG. 11. In addition, in FIG. 11, the electrodes 212A are connected to the bus line 322 through the vias VVC that extend between the electrode metal layer 210 and the underlying metal layer 320, and the vias VVC are arranged in a zig-zag path.

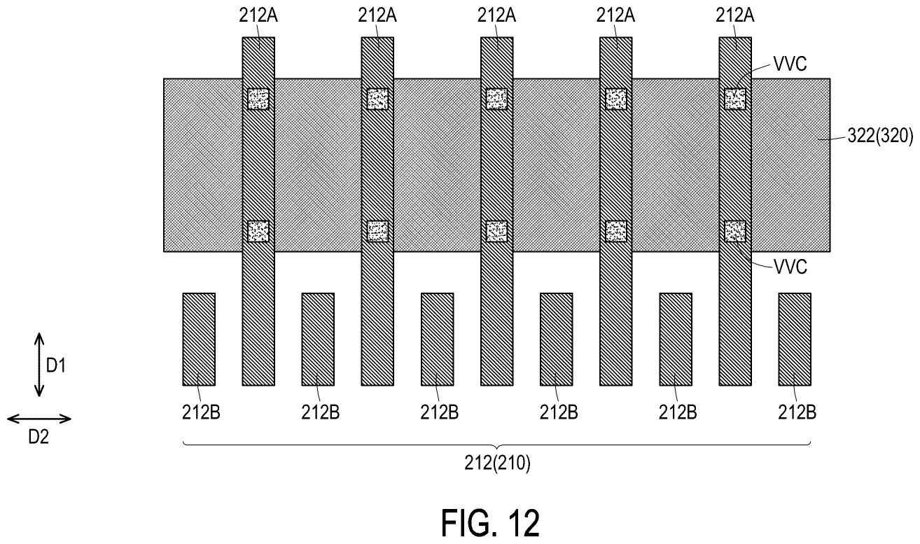

Referring to FIG. 12, an electrode metal layer 210 and an underlying metal layer 320 may be considered as an implemental example of the electrode metal layer 120 and the underlying metal layer 150 shown in the previous embodiment. The electrode metal layer 210 and the underlying metal layer 320 are substantially similar to the same component depicted in FIG. 10 and thus the descriptions for the electrode metal layer 210 and the underlying metal layer 320 in FIG. 10 are applicable to the embodiment of FIG. 12. In addition, in FIG. 12, the electrodes 212A are connected to the bus line 322 through the vias VVC that extend between the electrode metal layer 210 and the underlying metal layer 320, and specifically, each of the electrodes 212A is connected to the bus line 322 through two vias VVC. In other words, each of the electrodes 212A overlaps two vias VVC.

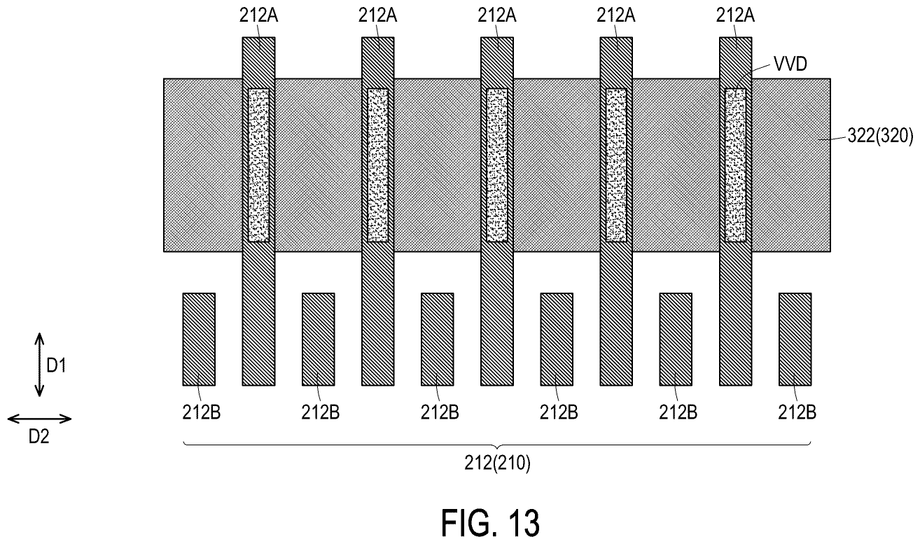

Referring to FIG. 13, an electrode metal layer 210 and an underlying metal layer 320 may be considered as an implemental example of the electrode metal layer 120 and the underlying metal layer 150 shown in the previous embodiment. The electrode metal layer 210 and the underlying metal layer 320 are substantially similar to the same component depicted in FIG. 10 and thus the descriptions for the electrode metal layer 210 and the underlying metal layer 320 in FIG. 10 are applicable to the embodiment of FIG. 13. In addition, in FIG. 13, the electrodes 212A are connected to the bus line 322 through the vias VVD that extend between the electrode metal layer 210 and the underlying metal layer 320, and specifically, each of the vias VVD has an elongated shape along a corresponding one of the electrodes 212A. Each of the vias VVD has a greater dimension in the direction D1 than the dimension in the direction D2 and overlaps one of the electrode 212A in the electrode metal layer 210 and the bus line 322 in the underlying metal layer 320.

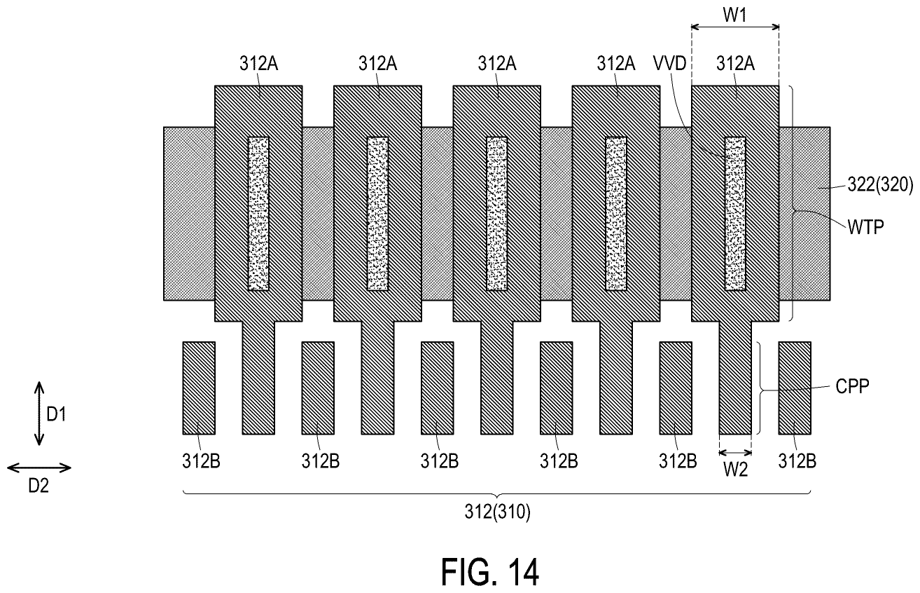

Referring to FIG. 14, an electrode metal layer 310 and an underlying metal layer 320 may be considered as an exemplary implement of the electrode metal layer 120 and the underlying metal layer 150 shown in the previous embodiment. The underlying metal layer 320 is substantially similar to the same component depicted in FIG. 10 and thus the descriptions for the underlying metal layer 320 in FIG. 10 are applicable to the embodiment of FIG. 14. The electrode metal layer 310 includes finger electrodes 312. Each of the finger electrodes 312 extends in the direction D1 and arranged beside another of the finger electrodes 312. Two adjacent finger electrodes 312 are indicated as the electrode 312A and the electrode 312B herein. The electrode 312A extends exceeding the electrode 312B in the direction D1 and crosses the bus lines 322 while the electrodes 312B are spaced from the bus lines 322 in the direction D1. The bus line 322 is connected to each of the electrodes 312A through a via VVD extending between the electrode metal layer 310 and the underlying metal layer 320 such that all of the electrodes 312A are connected to the bus line 322. In addition, each of the electrode 312A has a widen terminal portion WTP overlapping the bus line 322. Specifically, a width W1 of the widen terminal portion WTP of the electrode 312A is greater than a width W2 of another portion of the electrode 312A. In some embodiments, the portion of the electrode 312A having the width W2 may include a coupling portion CPP that is next to one of the electrodes 312B and contributes to the capacitance coupling effect of the finger electrodes 312. Each of the vias VVD has a greater dimension in the direction D1 than the dimension in the direction D2 and overlaps the widen terminal portion WTP of one of the electrode 312A in the electrode metal layer 310 and the bus line 322 in the underlying metal layer 320. In some embodiments, the dimension of each via VVD in the direction D2 may be smaller than width W1 of the widen terminal portion WTP of the electrode 312A. In some embodiments, the dimension of each via VVD in the direction D2 may be greater than width W2 of the coupling portion CPP of the electrode 312A.

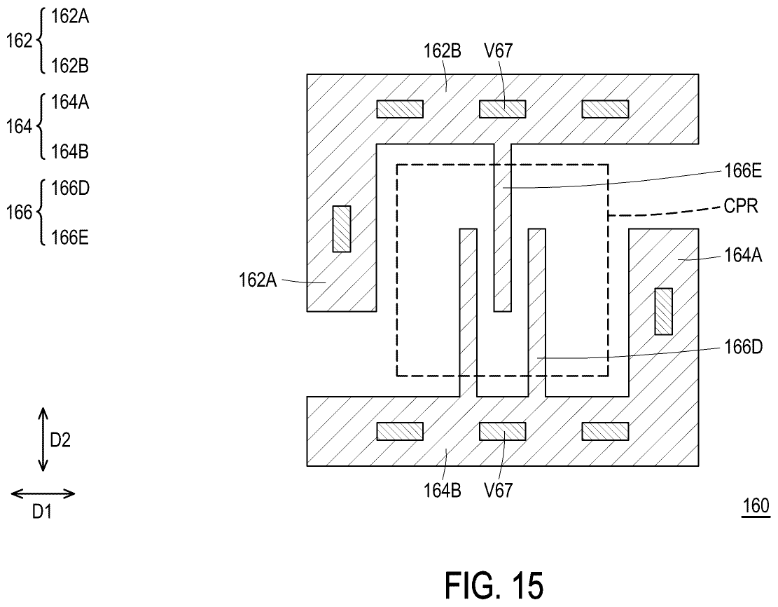

FIGS. 15-17 schematically illustrate further metal layers in the electronic device in accordance with some embodiments of the disclosure. In FIG. 15, a metal layer 160 is applicable to the electronic device 100 in FIG. 1 to be disposed over the electrode metal layer 140 in the capacitor structure 102. For example, when being applied in the electronic device 100 in FIG. 1, the metal layer 160 is the (j+1)^{th} metal layer ML right above the electrode metal layer 140 (the j^{th} metal layer), but the disclosure is not limited thereto. The metal layer 160 includes a bus feature 162, an opposite bus feature 164 and finger electrodes 166. The bus feature 162 includes a bus line portion 162A and a bus connection portion 162B connected to the bus line portion 162A, and the opposite bus feature 164 includes an opposite bus line portion 164A and an opposite bus connection portion 164B connected to the opposite bus line portion 164A. In some embodiments, the bus line portion 162A and the opposite bus line portion 164A are arranged in parallel to the finger electrodes 166 and the finger electrodes 166 are arranged in parallel to each other between the bus line portion 162A and the opposite bus line portion 164A. In addition, the bus connection portion 162B extends in a direction D1 intersecting the bus line portion 162A to form the bus feature 162 having an L-shape and the opposite bus connection portion 164B extends in a direction D1 intersecting the opposite bus line portion 164A to form the bus feature 164 having an L-shape. Three finger electrodes 166 are shown in FIG. 15 and the finger electrodes 166 may include odd electrodes 166D connected to the opposite bus connection portion 164B and an even electrode 166E connected to the bus connection portion 162B. Therefore, the finger electrodes 166 are connected to the bus features in the same layer (the metal layer 160).

In some embodiments, referring to FIGS. 4 and 15, the bus feature 162 in the metal layer 160 may be connected to the bus lines 142 through the vias V56A and V56B and connected to the bus lines 142 in the electrode metal layer 140 through the vias V56 overlapping the bus lines 142 and the bus connection portion 162B. In addition, the bus feature 164 in the metal layer 160 may be connected to the even electrodes 146E in the electrode metal layer 140 through the vias V56C and V56D and connected to the opposite bus lines 144 through the vias V56 overlapping the opposite bus lines 144 and the opposite bus connection portion 164B.

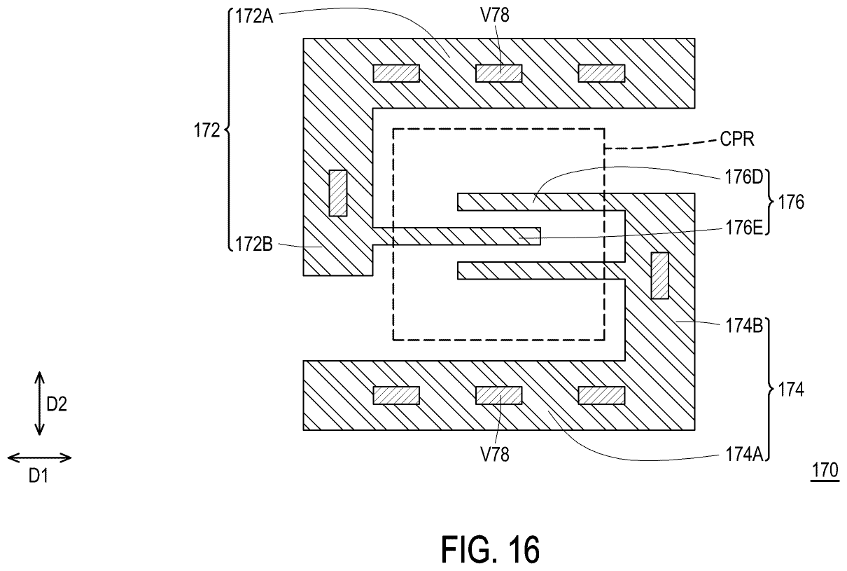

In FIG. 16, the metal layer 170 includes a bus feature 172, an opposite bus feature 174 and finger electrodes 176. The bus feature 172 includes a bus line portion 172A and a bus connection portion 172B connected to the bus line portion 172A, and the opposite bus feature 174 includes an opposite bus line portion 174A and an opposite bus connection portion 174B connected to the opposite bus line portion 174A. In some embodiments, the bus line portion 172A and the opposite bus line portion 174A are arranged in parallel to the finger electrodes 176 and the finger electrodes 176 are arranged in parallel to each other between the bus line portion 172A and the opposite bus line portion 174A. In addition, the bus line portion 172A extends in a direction D1 intersecting the bus connection portion 172B to form the bus feature 172 having an L-shape and the opposite bus line portion 174A extends in the direction D1 intersecting the opposite bus connection portion 174B to form the bus feature 174 having an L-shape. Three finger electrodes 176 are shown in FIG. 16 and the finger electrodes 176 may include odd electrodes 176D connected to the opposite bus connection portion 174B and an even electrode 176E connected to the bus connection portion 172B.

In some embodiments, the bus feature 172 in the metal layer 170 may overlap and correspond to the shape of the bus feature 162 in the metal layer 160, and the opposite bus feature 174 in the metal layer 170 may overlap and correspond to the shape of the opposite bus feature 164 in the metal layer 160. However, the finger electrodes 176 in the metal layer 170 extend in the direction D1 while the finger electrodes 166 in the metal layer 160 extend in the direction D2 intersecting the direction D2. In addition, vias V67 shown in FIG. 15 are further disposed between the metal layer 160 and the metal layer 170. The bus feature 172 in the metal layer 170 is connected to the bus feature 162 in the metal layer 160 through the vias V67 overlapping the bus feature 162 shown in FIG. 15 and the opposite bus feature 174 is connected to the opposite bus feature 164 through the vias V67 overlapping the opposite bus feature 164 shown in FIG. 15.

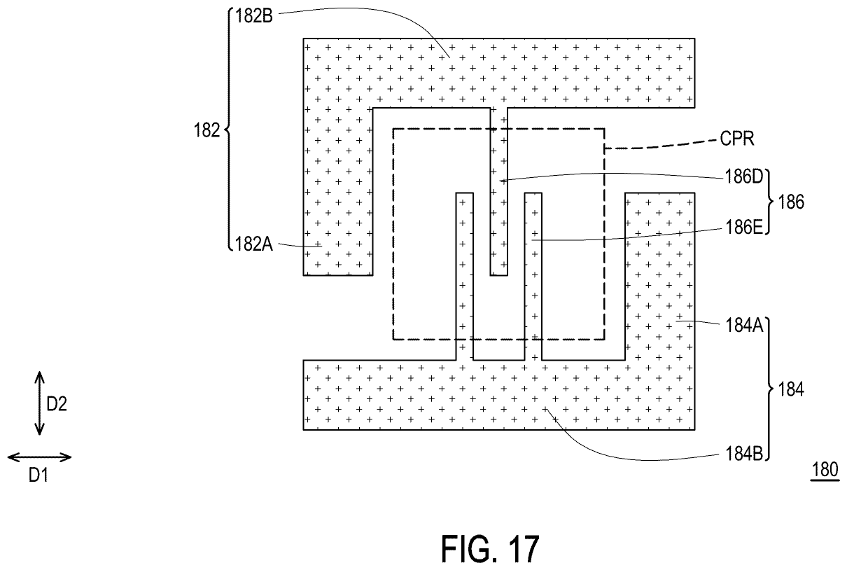

In FIG. 17, a metal layer 180 includes a bus feature 182, an opposite bus feature 184 and finger electrodes 186. The bus feature 182 includes a bus line portion 182A and a bus connection portion 182B connected to the bus line portion 182A, and the opposite bus feature 184 includes an opposite bus line portion 184A and an opposite bus connection portion 184B connected to the opposite bus line portion 184A. In some embodiments, the bus line portion 182A and the opposite bus line portion 184A are arranged in parallel to the finger electrodes 186 and the finger electrodes 186 are arranged in parallel to each other between the bus line portion 182A and the opposite bus line portion 184A. In addition, the bus connection portion 182B extends in a direction D1 intersecting the bus line portion 182A to form the bus feature 182 having an L-shape and the opposite bus connection portion 184B extends in a direction D1 intersecting the opposite bus line portion 184A to form the bus feature 184 having an L-shape. Three finger electrodes 186 are shown in FIG. 17 and the finger electrodes 186 may include odd electrodes 186D connected to the opposite bus connection portion 184B and an even electrode 186E connected to the bus connection portion 182B.

In some embodiments, the bus feature 182 in the metal layer 180 may overlap and correspond to the shape of the bus feature 172 in the metal layer 170, and the opposite bus feature 184 in the metal layer 180 may overlap and correspond to the shape of the opposite bus feature 174 in the metal layer 170. However, the finger electrodes 186 in the metal layer 180 extend in the direction D2 while the finger electrodes 176 in the metal layer 170 extend in the direction D1 intersecting the direction D2. In addition, vias V78 shown in FIG. 16 are further disposed between the metal layer 170 and the metal layer 180. The bus feature 182 in the metal layer 180 is connected to the bus feature 172 in the metal layer 170 through the vias V78 overlapping the bus feature 172 shown in FIG. 16 and the opposite bus feature 184 is connected to the opposite bus feature 174 through the vias V78 overlapping the opposite bus feature 174 shown in FIG. 16.

In some embodiments, an implement example of the capacitor structure 102 shown in FIG. 1 may be constructed by the underlying metal layer 150 and the electrode metal layers 120˜140 shown in FIGS. 1˜5 and the metal layers 160˜180 shown in FIGS. 15˜17. In some embodiments, the underlying metal layer 150 and the electrode metal layers 120˜140 shown in FIGS. 1˜5 and the metal layers 160˜180 shown in FIGS. 15˜17 are consecutively stacked metal layers among the metal layers ML form in the electronic device 100, and for example, are the 2^{nd} to 8^{th} metal layers ML, but the disclosure is not limited thereto. Specifically, the capacitance of the capacitor structure 102 is built by the capacitor coupling effect of the finger electrodes 126, 136, and 146 in the electrode metal layers 120˜140 shown in FIGS. 1˜5 and the finger electrodes 166, 176 and 186 in the metal layers 160˜180 shown in FIGS. 15˜17. Therefore, the finger electrodes 126, 136, 146, 166, 176 and 186 may be considered as capacitor electrodes. The bus lines/features and opposite bus lines/features in the underlying metal layer 150 and the electrode metal layers 120˜140 shown in FIGS. 1˜5, and the metal layers 160˜180 shown in FIGS. 15˜17 are metal features for achieving the electricity connection for the finger electrodes 126, 136, 146, 166, 176 and 186. In some embodiments, the underlying bus lines 152, the bus lines 122, the bus lines 132, the bus lines 142, the bus feature 162, the bus feature 172 and the bus feature 182 are electrically connected together and the opposite underlying bus lines 154, the opposite bus lines 124, the opposite bus lines 134, the opposite bus lines 144, the opposite bus feature 164, the opposite bus feature 174 and the opposite bus feature 184 are electrically connected together. In some embodiments, the odd electrodes and the even electrodes among the finger electrodes in the same metal layer are respectively connected to different voltages through corresponding bus features and the insulation structure INS is disposed between the odd electrodes and the even electrodes so that the capacitance coupling effect between the odd electrodes and the even electrodes is able to be induced.

In some embodiments, the finger electrodes in the electrode metal layers are arranged in a fine pitch rule, but the fine pitch may be disadvantageous to the arrangement of the interlayer vias since unwanted failures/defects may be caused due to the fine pitch arrangement of the interlayer vias. Therefore, as shown in the above embodiments, the finger electrodes connected to the same electricity terminal are connected to different bus lines alternately so that the interlayer vias connecting the finger electrodes are arranged in a loosen pitch than the finger electrodes connected to the same electricity terminal, which is beneficial to prevent from unwanted failures/defects due to small via pitch. In some embodiments, the finger electrodes in the bottom most layer of the electrode metal layer are the bottom most capacitor electrodes and the underlying bus features in the underlying metal layer are exclusively connected to the bottom most capacitor electrodes. Accordingly, all the finger electrodes in the electrode metal layers are connected to the bus features in both the upper metal layer and the lower metal layer, which is beneficial to reduce the resistance of the capacitor structure and is advantageous to the quality of the capacitor structure. Thereby, a good quality electronic device is achieved.

In some embodiments of the disclosure, a capacitor structure including electrode metal layers sequentially disposed over a substrate, wherein each of the electrode metal layers includes bus lines, opposite bus lines and finger electrodes arranged in parallel between the bus lines and the opposite bus lines, wherein odd electrodes of the finger electrodes in the each of the electrode metal layers are connected to the bus lines in an adjacent layer of the electrode metal layers, and even electrodes of the finger electrodes in the each of the electrode metal layers are connected to the opposite bus lines in the adjacent layer of the metal layers; an underlying metal layer disposed under a bottom most layer of the electrode metal layers and including an underlying bus line; underlying conductive vias connecting the odd electrodes of the finger electrodes in the bottom most layer of the electrode metal layers to the underlying bus line in the underlying metal layer; and interlayer conductive vias, wherein two adjacent odd electrodes of the finger electrodes in the bottom most layer of the electrode metal layers are connected to different bus lines in the adjacent layer of the electrode metal layers through the interlayer conductive vias. The underlying bus line in the underlying metal layer is electrically connected to the bus lines in the electrode metal layers. The underlying metal layer further includes an opposite underlying bus line connected to the even electrodes of the finger electrodes in the bottom most layer of the electrode metal layers. The capacitor structure further includes an insulation structure filling a space between the underlying bus line and the opposite underlying bus line. The insulation structure includes an oxide insulation material. The finger electrodes in one layer of the electrode metal layers are extended in a direction intersected with the finger electrodes in a next layer of the electrode metal layers. The bus lines in the each of the electrode metal layers includes a first bus line and a second bus line, and the odd electrodes of the finger electrodes in the each of the electrode metal layers being alternately connected to the first bus line and second bus line in the adjacent layer of the electrode metal layers. All of the odd electrodes of the finger electrodes in the bottom most layer of the electrode metal layers is connected to the underlying bus line. The underlying conductive vias are arranged in a linear path along an extending direction of the underlying bus line. The underlying conductive vias are arranged in a zig-zag path. Each of the odd electrodes of the finger electrodes in the bottom most layer of the electrode metal layers is connected to the underlying bus line in the underlying metal layer through two of the underlying conductive vias. Each of the odd electrodes of the finger electrodes in the bottom most layer of the electrode metal layers has a widen terminal portion overlapping the underlying bus line. Each of the underlying conductive vias has an elongated shape along a corresponding one of the odd electrodes of the finger electrodes in the bottom most layer of the electrode metal layers. The underlying bus line has a width greater than the bus lines and the opposite bus lines in the electrode metal layers.

In some embodiments of the disclosure, an electronic device includes metal layers disposed sequentially on a substrate, wherein each layer of an i^{th} layer to an j^{th} layer of the metal layers comprises bus lines, opposite bus lines and finger electrodes arranged in parallel between the bus lines and the opposite bus lines, the finger electrodes in two adjacent layers of the i^{th} layer to the jth layer extend in different directions, an (i−1)^{th} layer of the metal layers comprises an underlying bus line connected to odd electrodes of the finger electrodes in the i^{th} layer of the metal layers and an opposite underlying bus line connected to even electrodes of the finger electrodes in the i^{th} layer of the metal layers, j>i, and i is greater than 2; and an insulation structure disposed on the substrate, wherein the insulation structure continuously extends in a lateral spacing between the underlying bus line and the opposite underlying bus line. The bus lines in the (i+1)^{th} layer of the metal layers include a first bus line and a second bus line, odd electrodes of the finger electrodes in the i^{th} layer of the metal layers are alternately connected to the first bus line and the second bus line through interlayer conductive vias extending between the i^{th} layer of the metal layers and the (i+1)^{th} layer of the metal layers. The odd electrodes of the finger electrodes in the i^{th} layer of the metal layers are connected to the underlying bus line through underlying conductive vias extending between the (i−1)^{th} layer of the metal layers and the i^{th} layer of the metal layers. The underlying bus line in the (i−1)^{th} layer of the metal layers is connected to the bus lines in the i^{th} layer of the metal layers.

In some embodiments of the disclosure, a method of fabricating an electronic device including sequentially forming metal layers on a substrate, wherein each layer of an i^{th} layer to an j^{th} layer of the metal layers includes bus lines, opposite bus lines and finger electrodes arranged in parallel between the bus lines and the opposite bus lines, the finger electrodes in two adjacent layers of the i^{th} layer to the j^{th} layer extend in different directions, an (i−1)^{th} layer of the metal layers includes an underlying bus line and an opposite underlying bus line, j>i, and i is greater than 2; connecting odd electrodes of the finger electrodes in the i^{th} layer of the metal layers to the underlying bus line; connecting even electrodes of the finger electrodes in the i^{th} layer of the metal layers to the opposite underlying bus line; and filling an insulation structure in a lateral spacing between the underlying bus line and the opposite underlying bus line.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A capacitor structure comprising:
a substrate;
electrode metal layers sequentially disposed over the substrate, wherein each of the electrode metal layers comprises bus lines, opposite bus lines and finger electrodes arranged in parallel between the bus lines and the opposite bus lines, wherein odd electrodes of the finger electrodes in the each of the electrode metal layers are connected to the bus lines in an adjacent layer of the electrode metal layers, and even electrodes of the finger electrodes in the each of the electrode metal layers are connected to the opposite bus lines in the adjacent layer of the electrode metal layers;
an underlying metal layer disposed under a bottom most layer of the electrode metal layers and comprising an underlying bus line;
underlying conductive vias, connecting the odd electrodes of the finger electrodes in the bottom most layer of the electrode metal layers to the underlying bus line in the underlying metal layer; and
interlayer conductive vias, wherein two adjacent odd electrodes of the finger electrodes in the bottom most layer of the electrode metal layers are connected to different bus lines in the adjacent layer of the electrode metal layers through the interlayer conductive vias.

2. The capacitor structure of claim 1, wherein the underlying bus line in the underlying metal layer is electrically connected to the bus lines in the electrode metal layers.

3. The capacitor structure of claim 1, wherein the underlying metal layer further comprising an opposite underlying bus line connected to the even electrodes of the finger electrodes in the bottom most layer of the electrode metal layers.

4. The capacitor structure of claim 3, further comprising an insulation structure filling a space between the underlying bus line and the opposite underlying bus line.

5. The capacitor structure of claim 4, wherein the insulation structure comprises an oxide insulation material.

6. The capacitor structure of claim 1, wherein the finger electrodes in one layer of the electrode metal layers are extended in a direction intersected with the finger electrodes in a next layer of the electrode metal layers.

7. The capacitor structure of claim 1, wherein the bus lines in the each of the electrode metal layers comprises a first bus line and a second bus line, and the odd electrodes of the finger electrodes in the each of the electrode metal layers being alternately connected to the first bus line and second bus line in the adjacent layer of the electrode metal layers.

8. The capacitor structure of claim 1, wherein all of the odd electrodes of the finger electrodes in the bottom most layer of the electrode metal layers is connected to the underlying bus line.

9. The capacitor structure of claim 1, wherein the underlying conductive vias are arranged in a linear path along an extending direction of the underlying bus line.

10. The capacitor structure of claim 1, wherein the conductive vias connected to the bottom most layer are arranged in a zig-zag path.

11. The capacitor structure of claim 1, wherein each of the odd electrodes of the finger electrodes in the bottom most layer of the electrode metal layers is connected to the underlying bus line in the underlying metal layer through two of the underlying conductive vias.

12. The capacitor structure of claim 1, wherein each of the odd electrodes of the finger electrodes in the bottom most layer of the electrode metal layers has a widen terminal portion overlapping the underlying bus line.

13. The capacitor structure of claim 1, wherein each of the underlying conductive vias has an elongated shape along a corresponding one of the odd electrodes of the finger electrodes in the bottom most layer of the electrode metal layers.

14. The capacitor structure of claim 1, wherein the underlying bus line has a width greater than the bus lines and the opposite bus lines in the electrode metal layers.

15. The capacitor structure of claim 1, wherein linewidths of the finger electrodes are identical to each other.

16. An electronic device, comprising:
a substrate;
metal layers disposed sequentially on the substrate, wherein each layer of an i^{th} layer to an j^{th} layer of the metal layers comprises bus lines, opposite bus lines and finger electrodes arranged in parallel between the bus lines and the opposite bus lines, the finger electrodes in two adjacent layers of the i^{th} layer to the j^{th} layer extend in different directions, an (i−1)^{th} layer of the metal layers comprises an underlying bus line connected to odd electrodes of the finger electrodes in the i^{th} layer of the metal layers and an opposite underlying bus line connected to even electrodes of the finger electrodes in the i^{th} layer of the metal layers, j>i, and i is greater than 2; and
an insulation structure disposed on the substrate, wherein the insulation structure continuously extends in a lateral spacing between the underlying bus line and the opposite underlying bus line.

17. The electronic device of claim 16, wherein the bus lines in the (i+1)^{th} layer of the metal layers comprises a first bus line and a second bus line, odd electrodes of the finger electrodes in the i^{th} layer of the metal layers are alternately connected to the first bus line and the second bus line through interlayer conductive vias extending between the i^{th} layer of the metal layers and the (i+1)^{th} layer of the metal layers.

18. The electronic device of claim 17, wherein the odd electrodes of the finger electrodes in the i^{th} layer of the metal layers are connected to the underlying bus line through underlying conductive vias extending between the (i−1)^{th} layer of the metal layers and the i^{th} layer of the metal layers.

19. The electronic device of claim 16, wherein the underlying bus line in the (i−1)^{th} layer of the metal layers is connected to the bus lines in the i^{th} layer of the metal layers.

20. A method of fabricating an electronic device, comprising:
sequentially forming metal layers on a substrate, wherein each layer of an i^{th} layer to an j^{th} layer of the metal layers comprises bus lines, opposite bus lines and finger electrodes arranged in parallel between the bus lines and the opposite bus lines, the finger electrodes in two adjacent layers of the i^{th} layer to the j^{th} layer extend in different directions, an (i−1)^{th} layer of the metal layers comprises an underlying bus line and an opposite underlying bus line, j>i, and i is greater than 2;
connecting odd electrodes of the finger electrodes in the i^{th} layer of the metal layers to the underlying bus line;
connecting even electrodes of the finger electrodes in the i^{th} layer of the metal layers to the opposite underlying bus line; and
filling an insulation structure in a lateral spacing between the underlying bus line and the opposite underlying bus line.
